(19) United States
(12) Patent Application Publication
(10) Pub. No.: US 2006/0043066 A1
(43) Pub. Date: Mar. 2, 2006

(54) Processes for pre-tapering silicon or silicon-germanium prior to etching shallow trenches

(76) Inventor: Thomas A. Kamp, San Jose, CA (US)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(21) Appl. No.: 10/925,921

(22) Filed: Aug. 26, 2004

(51) Int. Cl. B44C 1/22; H01L 21/302

(52) U.S. Cl. 216/67; 438/706; 438/710; 216/79

(57) ABSTRACT

A process for pre-tapering features in a material, such as silicon, prior to etching shallow trenches in the material includes opening a hard mask over the material such that first pre-tapered features are formed in the material. The process can include a hard mask overetch step, which modifies the profile of the first pre-tapered features to form second pre-tapered features in the material. Shallow trench isolation features are formed in the pre-tapered material.

### BACKGROUND

During the manufacture of semiconductor-based products, such as integrated circuits, etching and/or deposition steps are used to build up or remove layers of material on a semiconductor substrate. A conventional etching procedure uses process gas energized into a plasma state to plasma etch a layer of material.

Plasma etching is used to provide shallow trench isolation (“STI”) of individual transistors in an integrated circuit. STI can be used to form a trench that can, for example, electrically isolate individual transistors in an integrated circuit. Electrical isolation prevents current leakage between two adjacent devices (for example, transistors).

### SUMMARY

Processes for forming pre-tapered features in silicon or silicon-germanium are provided. A preferred embodiment of the processes comprises providing a semiconductor structure in a plasma processing chamber, wherein the semiconductor structure comprises a layer of silicon or silicon-germanium, a hard mask over the silicon or silicon-germanium layer, and a patterned soft mask over the hard mask. A first etching gas mixture is supplied into the plasma processing chamber and energized to produce a first plasma, which etches openings through the hard mask and etches first pre-tapered features in the silicon or silicon-germanium layer.

A process according to another preferred embodiment comprises supplying a second etching gas mixture into the plasma processing chamber, and forming a second plasma from the second etching gas mixture. The second plasma overetches the hard mask, which modifies and/or enlarges the first features to form second pre-tapered features in the silicon or silicon-germanium layer.

A preferred embodiment of a process for forming shallow trenches in a silicon or silicon-germanium layer comprises providing in a plasma processing chamber a semiconductor structure comprising a silicon or silicon-germanium layer, a hard mask over the silicon or silicon-germanium layer, and a patterned soft mask over the hard mask. A first etching gas mixture is supplied into the plasma processing chamber and energized to produce a first plasma. The first plasma etches openings through the hard mask and first pre-tapered features in the silicon or silicon-germanium layer. A second etching gas mixture is supplied into the plasma processing chamber and energized to produce a second plasma. The second plasma overetches the hard mask, which modifies and/or enlarges the first features to form second pre-tapered features in the silicon or silicon-germanium layer. The process comprises terminating the supply of the second etching gas mixture into the plasma processing chamber, supplying a third process gas into the plasma processing chamber, and energizing the third process gas mixture to form a third plasma. The third plasma etches shallow trenches in the silicon or silicon-germanium layer.

### BRIEF DESCRIPTION OF THE DRAWING FIGURES

FIG. 1 depicts a semiconductor structure prior to being etched using a process according to a preferred embodiment.

FIG. 2 depicts the semiconductor structure shown in FIG. 1 after opening the hard mask and forming pre-tapered features in an underlying layer by a process according to a preferred embodiment.

FIG. 3 depicts the semiconductor structure after etching a shallow trench feature in the underlying layer.

FIG. 4 depicts an exemplary plasma processing chamber that can be used for practicing preferred embodiments of the processes.

FIG. 5 is a scanning electron (SEM) micrograph of a pre-tapered structure formed in a silicon wafer by a process according to a preferred embodiment.

FIG. 6 is an SEM micrograph of a pre-tapered structure formed in another region of the silicon wafer shown in FIG. 5.

### DETAILED DESCRIPTION OF PREFERRED EMBODIMENTS

Processes for producing shallow trench isolation (STI) features in silicon can include steps of forming a hard mask over silicon, patterning a soft mask over the hard mask, patterning the hard mask through the soft mask, and then etching shallow trenches in the silicon. After removing the soft mask, shallow trenches in the silicon are back-filled with a dielectric material. Exemplary shallow trench plasma etching processes are disclosed in commonly-assigned U.S. Pat. Nos. 6,218,309 and 6,287,974, which are incorporated herein by reference in their entireties.

As used herein, the term “recessed” means that etched features formed in a material have a sidewall profile of about 85° to about 90° (i.e., a substantially vertical, or a vertical, 90°, sidewall profile). As used herein, the term “tapered” means that etched features in a material have a sidewall profile that is less than about 85°. In some hard mask shallow trench isolation processes, it is desirable to have top rounding and/or no recessing in silicon at the beginning of the shallow trench etch step. For example, U.S. Pat. No. 5,807,789 discloses a shallow trench structure having a tapered profile and rounded corners. Top rounding of shallow trench isolation features also is disclosed in U.S. Pat. Nos. 6,218,309 and 6,287,974.

Hard mask STI top rounding can be achieved by performing a top rounding step separately from the hard mask open step, prior to etching trenches in the silicon. However, it has been determined that in such processes, during the hard mask opening step and/or approximately the first few seconds of STI, features that have substantially vertical or vertical side walls (i.e., recessed features) can be etched in silicon. Such recessed features are undesirable because they can adversely affect the electrical performance of devices built on the substrate.

The transition from hard mask open to shallow trench isolation presents challenges that can decrease the effectiveness of the top rounding and/or trench etch steps, such as the presence of native oxides and/or polymer residues and/or inconsistent passivation generation due to stabilization steps. Moreover, post-mask open and photoresist strip top rounding processes can produce undesirable effects in silicon, such as sub-trenches, double slopes, poor mask selectivity, vertical silicon recessing and/or micromasks, and these effects can be transferred to the trench etch step.

It has been determined that, at the initiation of the shallow trench isolation step, it is preferable that the material in which the shallow trenches are to be formed is in a pre-tapered condition; i.e., tapered features have been formed in this material before beginning the trench etching step.

It also has been determined that in order to produce such pre-tapered features prior to performing shallow trench isolation, the hard mask opening step is not stopped when the etching front reaches the pad oxide/substrate interface. Rather, the etching is continued past this interface and into the material in which the shallow trenches are to be formed. The hard mask open step preferably produces a tapered profile in this material. The tapered profile is referred to herein as “pre-tapered” because it is formed before shallow trench isolation. The hard mask open step preferably removes a depth of only about several nanometers of the material in which the trenches are to be formed, but without recessing that material. The hard mask open step provides an initial step in the pre-tapering process.

The pre-tapering process preferably also includes a hard mask over-etch step following the hard mask open step. The hard mask overetch step achieves the desired pre-tapered profile in the silicon or silicon-germanium prior to etching trenches in the silicon or silicon-germanium.

The profile of the pre-tapered features that are formed in silicon or silicon-germanium is achieved by the appropriate selection of passivation species and silicon or silicon-germanium etching selectivity. Particularly, during the hard mask open step, carbon-based polymer deposits provide passivation that guides the profile of pre-tapered features that are formed. At hard mask open endpoint, which is after the etching has opened the hard mask and etched pre-tapered features in underlying silicon or silicon-germanium, etching is continued, but with a different passivation species, preferably a silicon-based glass polymer. The hard mask and silicon or silicon-germanium sidewall profile is determined by process parameters, which can include but are not limited to, etching gas mixture composition and flow rate, etching chamber pressure, applied power level to electrodes, and etching time.

It is desirable to have a reduced silicon or silicon-germanium etch rate in relation to the hard mask etch rate. A reduced silicon or silicon-germanium etch rate can be achieved by enhanced passivation formation at the etching front. Particularly, a relatively heavier passivation formation at etching front corners is more desirable for producing a slight silicon or silicon-germanium taper.

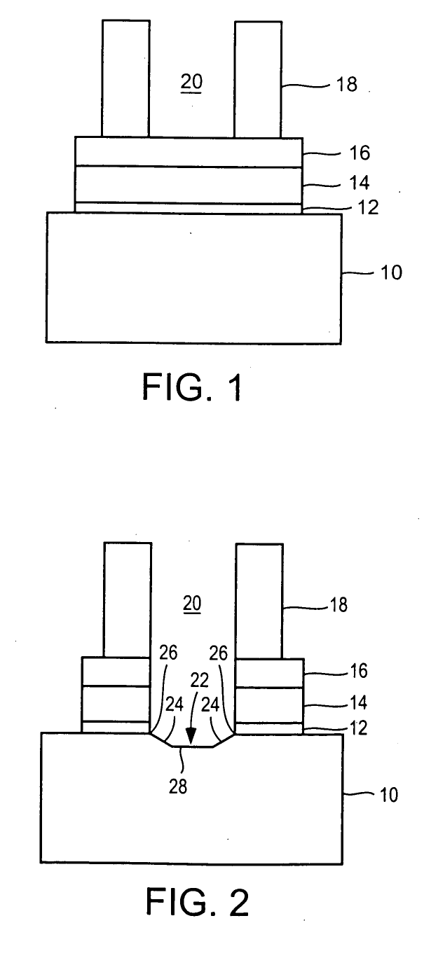

A preferred embodiment of a process of pre-tapering silicon or silicon-germanium prior to shallow trench isolation is described with reference to FIGS. 1 and 2. FIG. 1 depicts an exemplary semiconductor structure prior to performing pre-tapering and shallow trench isolation processing. The semiconductor structure includes a substrate 10 and an overlying stack of layers. The exemplary stack of layers shown in FIG. 1 includes a pad oxide layer 12 over the substrate 10, a hard mask 14 over the pad oxide layer 12, an optional bottom antireflective coating (BARC) 16 over the hard mask 14, and a photoresist layer 18 over the BARC 16. The BARC 16 and optional photoresist layer 18 are collectively referred to herein as the “soft mask.”

As shown in FIG. 1, the photoresist layer 18 includes a desired pattern of openings (only one such opening 20 is shown). For etching shallow trench structures in the substrate 10, the openings 20 are formed in the photoresist layer 18 at locations corresponding to the desired locations for the formation of respective shallow trenches in the substrate 10. The hard mask 14 and pad oxide layer 12 are opened by plasma etching at the location of the openings 20 to pattern the hard mask.

The substrate 10 is preferably of single crystal silicon, such as a single crystal silicon wafer. Alternatively, the substrate 10 can be polycrystalline silicon, or a silicon-germanium alloy. According to another embodiment, the substrate 10 can include a single crystal silicon, polycrystalline silicon or silicon-germanium layer that forms the upper surface of the substrate 10. For example, the substrate 10 can include a silicon layer formed on an insulator material, i.e., a silicon-on-insulator (SOI) structure. The silicon or silicon-germanium material of the substrate 10 can be doped or un-doped material.

The pad oxide layer 12 is preferably of SiO₂. The pad oxide layer 12 preferably has a thickness of up to about 30 nm (300 Å), such as from about 10 nm (100 Å) to about 20 nm (200 Å). The pad oxide layer 12 can be formed on the substrate 10 by any suitable process, such as by thermal oxidation of the substrate 10 in an oxygen-containing atmosphere, or by any suitable deposition process, such as chemical vapor deposition (CVD). The pad oxide layer 12 acts as a buffer layer.

The hard mask 14 is preferably of SiₓN_{y}, such as Si₃N₄. The hard mask 14 can have a thickness of from about 40 nm (400 Å) to about 200 nm (2000 Å), such as from about 80 nm (800 Å) to about 120 nm (1200 Å). The hard mask 14 can be formed on the pad oxide layer 12 by any suitable deposition process, for example, low-pressure chemical vapor deposition (LPCVD), plasma-enhanced chemical vapor deposition (PECVD), or the like. The pad oxide layer 12 and the hard mask 14 are removed in subsequent processes.

The BARC 16 can be composed of any suitable organic or inorganic material.

The photoresist layer 18 can be composed of any suitable resist material. The photoresist layer 18 is preferably composed of a carbon-based polymer that can be removed by stripping in an oxygen-containing atmosphere. The BARC preferably also is removed during the photoresist stripping process. During stripping of the soft mask, oxygen radicals and ion species react with the photoresist layer 18 and BARC 16. The process gas used for stripping the soft mask can have any suitable composition, for example, an O₂/N₂, O₂/H₂O, O₂/N₂/CF₄, or O₂/N₂/H₂O gas mixture.

FIG. 2 shows the semiconductor structure after the BARC 16, hard mask 14 and pad oxide layer 12 have been opened and pre-tapered features have been etched in the substrate 10 (only one such pre-tapered feature 22 is shown for simplicity). In a preferred embodiment, a step of the pre-tapering process opens the BARC 16, hard mask 14 and pad oxide layer 12 by plasma etching using a suitable etch chemistry. For this step, the etching gas mixture preferably comprises at least one gas having a formula of CₓH_{y}F_{z}, where x, y and z are each >0; oxygen-containing gas and inert gas. Preferably, the etching gas mixture contains CHF₃, inert gas and O₂. The inert gas can be, for example, argon, helium or mixtures thereof. The inert gas is included in the etching gas mixture to remove polymer deposits on the sidewalls of the hard mask 14 and pad oxide layer 12 during plasma etching to preferably achieve a substantially vertical, or vertical, sidewall structure for the hard mask and pad oxide openings, as shown in FIG. 2. The gas mixture can optionally contain a gas, such as HBr, effective to protect the photoresist layer 18 from deformation during the hard mask opening step.

The components of the etching gas mixture used to open the hard mask can have any suitable ratio that can preferably achieve a recessed structure for the hard mask and pad oxide, while forming desired pre-tapered features in silicon or silicon-germanium. Preferred approximate ranges for the gas flow rates of the components of the etching gas mixture for opening the hard mask are: CHF₃: about 50 to about 300 sccm; inert gas: up to about 750 sccm; O₂: up to about 40 sccm; HBr: 0 to about 40 sccm.

Preferably, the hard mask open step produces tapered features in the silicon or silicon-germanium having a depth of from about 3 nm to about 20 nm. Etch endpoint detection is preferably used to determine when the pad oxide layer 12 has been opened to reduce overetching of the hard mask with the gas mixture. For example, optical emission spectroscopy can be used to determine the end point of SiO₂.

The hard mask opening step preferably only initiates the pre-tapering process. That is, the pre-tapered features shown in FIG. 2 preferably are not formed entirely by the mask opening step. Preferably, a different etching gas mixture also is used for overetching the hard mask to result in the pre-tapered features shown in FIG. 2.

Preferably, once endpoint detection determines that the pad oxide layer 12 has been opened, the etching gas mixture used to open the hard mask is changed to a different etching gas mixture that is effective to overetch the hard mask and achieve the desired pre-tapered silicon or silicon-germanium structure. The hard mask overetch gas mixture preferably is oxygen-free, and preferably is a mixture of at least one gas having a formula of CₓH_{y}F_{z}, where x, y and z are each >0, and inert gas. Preferably, the etching gas mixture for overetching the hard mask contains CHF₃ and argon or helium. Preferred approximate ranges for the gas flow rates of the components of the overetching gas mixture are: CHF₃: from about 50 to about 300 sccm, and inert gas: up to about 750 sccm. The overetching step is preferably conducted for from about 5 seconds to about 45 seconds, more preferably from about 5 seconds to about 15 seconds, to achieve the desired features in silicon or silicon-germanium. Increasing the etching time increases the taper of the pre-tapered features.

As shown in FIG. 2, pre-tapered feature 22 resulting from the hard mask overetch step is defined by sidewalls 24, which preferably have a taper of from about 30° to about 85°. The sidewalls 24 may be entirely planar, as shown. The sidewalls 24 can be rounded at the interface 26 between the pad oxide layer 12 and the substrate 10. Pre-tapered feature 22 preferably has a depth of from about 1 nm (10 Å) to about 50 nm (500 Å), more preferably from about 1 nm to about 15 nm (150 Å). As shown in FIG. 2, the sidewalls 24 of the pre-tapered feature 22 preferably extend from the substrate 10/pad oxide 12 interface 26 to the bottom 28.

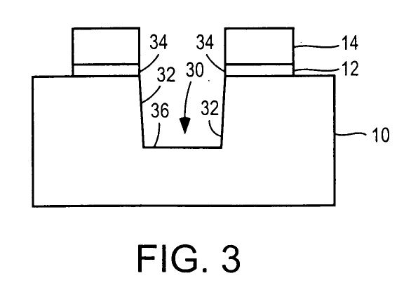

FIG. 3 shows the semiconductor structure after shallow trenches have been etched in the substrate 10 (only one such shallow trench 30 is shown for simplicity) following the hard mask overetch. The shallow trench etching gas mixture for silicon or silicon-germanium can be, for example, an HBr/O₂ etching gas mixture, a Cl₂/O₂ etching gas mixture. The shallow trenches 30 can typically have a depth of from about 50 nm (500 Å) to about 500 nm (5000 Å) and include sidewalls 32 having a taper of from about 60° to about 90° from the pad oxide 12/substrate 10 interface 34 to the shallow trench bottom 36.

Semiconductor structures, such as the semiconductor structure shown in FIGS. 1-3, can be processed by preferred embodiments of the processes in various types of plasma reactors. Such plasma reactors typically have energy sources that use RF energy, microwave energy or magnetic fields, for example, to produce a medium- to high density plasma. Preferred embodiments of the processes of pre-tapering silicon and etching shallow trenches can be carried out in an inductively-coupled plasma reactor. Embodiments of the processes can be practiced in a high-density plasma reactor, such as the inductively coupled TCP® 2300 plasma reactor, which is available from Lam Research Corporation, located in Fremont, Calif.

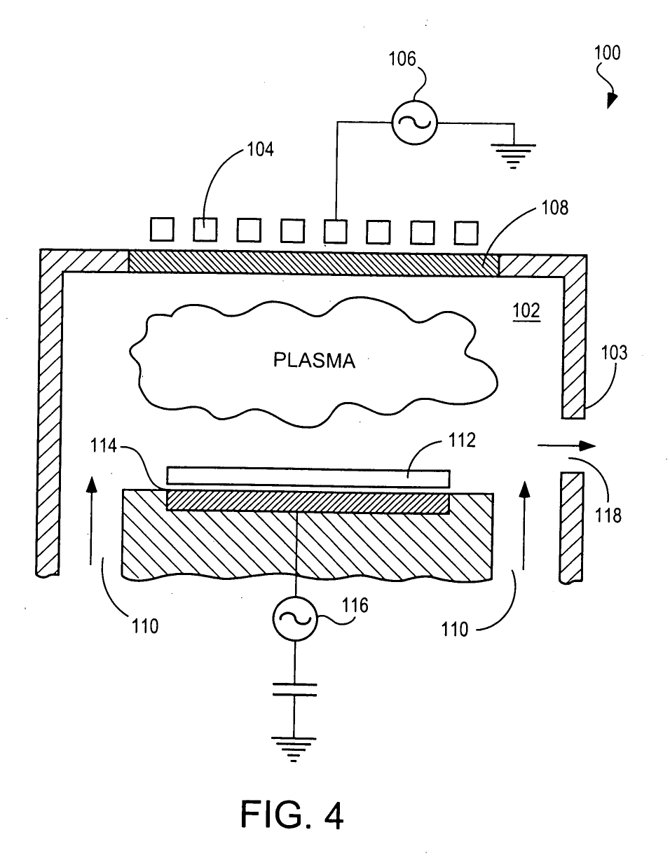

FIG. 4 illustrates an exemplary plasma processing apparatus 100 including an inductively-coupled plasma processing chamber 102 having a chamber wall 103. To provide an electrical path to ground, the chamber wall 103 can be made of metal and grounded. The plasma processing apparatus includes an inductive electrode 104, which is preferably a coil, such as a planar, spiral coil. The inductive electrode 104 is powered by an RF power source 106 via a matching network. A dielectric window 108 is disposed below the inductive electrode 104.

A gas port 110 is provided within the plasma processing chamber 102 for supplying process gas, for example, etching gas mixtures, into the RF-induced plasma region between the dielectric window 108 and a substrate 112 supported on a substrate support. The substrate support includes a chuck 114, which is preferably an electrostatic chuck (ESC) adapted to secure the substrate 112 by an electrostatic clamping force during plasma processing. Alternatively, the process gas may also be supplied from passages in the walls of the chamber, or through an injector arrangement. The ESC optionally functions as a bottom electrode and is preferably biased by an RF power source 116 (also typically via a matching network). If desired, the ESC can be supported on an RF-powered bottom electrode. The chuck 114 may optionally include a focus ring positioned around the bottom electrode.

The plasma processing chamber 102 can include an exhaust port 118 in fluid communication with a pump (not shown) located outside of chamber 102. The pump maintains a desired vacuum pressure inside the plasma processing chamber 102.

Desirable flow rates of the etch gas mixtures for the hard mask open and hard mask overetch steps can be selected based on various factors, including the type of plasma reactor, the power settings, the vacuum pressure in the reactor, and the dissociation rate for the plasma source. For an inductively-coupled plasma reactor, the plasma processing chamber is preferably operated at a pressure of from about 5 mT to about 100 mT for the hard mask opening step, and at a pressure of from about 1 mT to about 50 mT during the hard mask overetch step.

The substrate support supporting the semiconductor structure that is undergoing etching preferably is adapted to cool the substrate. In high- and medium density plasma reactors, it is typically sufficient to cool the substrate support to a temperature of from about −10 to about +80° C. For example, a semiconductor wafer can be electrostatically clamped and cooled by supplying a heat transfer fluid, such as helium, at a desired pressure between the wafer and top surface of the ESC.

Exemplary process conditions that can be used for forming a pre-tapered silicon or silicon-germanium structure, such as shown in FIG. 2, using an inductively-coupled plasma processing chamber, are as follows: Hard mask open: processing chamber pressure of 90 mT/coil power of 500 watts/bottom electrode voltage of 400 volts/100 sccm CHF₃/500 sccm helium or argon/15 sccm O₂/20 sccm HBr/substrate support temperature of about 60° C.

Hard mask overetch: 5 mT plasma processing chamber pressure/coil power of 500 watts/bottom electrode voltage of 400 volts/100 sccm CHF₃/100 sccm helium or argon/substrate support temperature of 60° C./etching time of 10 sec.

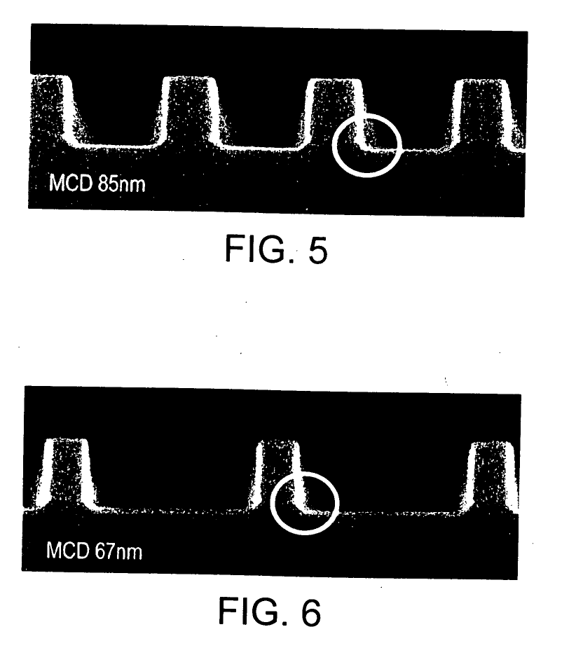

FIGS. 5 and 6 are SEM micrographs showing pre-tapered features (as-encircled) formed in two different regions of a silicon wafer using the above-describe exemplary process conditions for the respective hard mask open and overetch steps in an inductively-coupled plasma processing chamber. The structures shown in FIGS. 5 and 6 have a middle critical dimension (MCD) of about 85 nm and 67 nm, respectively.

In another preferred embodiment, a process for pre-tapering silicon or silicon-germanium can be carried out in a medium-density, parallel-plate plasma reactor. An exemplary suitable parallel-plate plasma reactor that can be used is the dual frequency plasma etch reactor described in commonly-assigned U.S. Pat. No. 6,090,304, which is hereby incorporated by reference in its entirety. In such reactors, etching gas can be supplied to a showerhead electrode from a gas supply and a capacitively-coupled plasma can be generated in the reactor by supplying RF energy from one or more RF sources to the showerhead electrode and/or a bottom electrode, or the showerhead electrode can be electrically grounded and RF energy at two different frequencies can be supplied to the bottom electrode.

In addition to a high-density, inductively-coupled plasma reactor or a medium-density, capacitively-coupled plasma reactor, any other suitable plasma reactor can be used to practice preferred embodiments of the processes for tapering silicon, such as a wave-excited reactor, for example, ECR (microwave) or helicon resonator.

The foregoing has described the principles, preferred embodiments and modes of operation of the present invention. However, the invention should not be construed as being limited to the particular embodiments discussed. Thus, the above-described embodiments should be regarded as illustrative rather than restrictive, and it should be appreciated that variations may be made in those embodiments by workers skilled in the art without departing from the scope of the present invention as defined by the following claims.

What is claimed is:

1. A process for pre-tapering a silicon layer or a silicon-germanium layer of a semiconductor structure, comprising:
providing a semiconductor structure in a plasma processing chamber, the semiconductor structure comprising a silicon layer or a silicon-germanium layer, a hard mask over the silicon layer or silicon-germanium layer, and a patterned soft mask over the hard mask;
supplying an etching gas mixture into the plasma processing chamber; and
forming a plasma from the etching gas mixture and (i) etching openings through the hard mask and (ii) etching pre-tapered features in the silicon layer or silicon-germanium layer with the plasma.

2. The process of claim 1, wherein the pre-tapered features have a depth of about 1 nm to about 20 nm.

3. The process of claim 1, wherein the etching gas mixture comprises CₓH_{y}F_{z}, where each of x, y and z is >0, oxygen-containing gas and inert gas.

4. The process of claim 3, wherein the etching gas mixture comprises CHF₃, inert gas, O₂ and optionally HBr.

5. The process of claim 4, wherein the etching gas mixture is supplied into the process chamber at a gas flow rate of from about 50 sccm to about 300 sccm of CHF₃, up to about 750 sccm of the inert gas, up to about 40 sccm of O₂, and from about 0 to about 40 sccm of HBr.

6. The process of claim 5, wherein the plasma is formed by inductively coupling RF energy into the plasma processing chamber which is at a pressure of from about 5 mT to about 100 mT.

7. The process of claim 1, wherein the semiconductor structure includes a pad oxide layer between the silicon or silicon-germanium layer and the hard mask, and the plasma forms openings defined by substantially vertical or vertical sidewalls in the hard mask and pad oxide layer.

8. The process of claim 7, wherein the semiconductor structure comprises the pad oxide layer between a silicon nitride layer and a single crystal silicon layer.

9. A process for pre-tapering a silicon layer or a silicon-germanium layer of a semiconductor structure, comprising:
providing a semiconductor structure in a plasma processing chamber, the semiconductor structure comprising a silicon layer or a silicon-germanium layer, a hard mask over the silicon layer or silicon-germanium layer, and a patterned soft mask over the hard mask;
supplying a first etching gas mixture into the plasma processing chamber; and
forming a first plasma from the first etching gas mixture and (i) etching openings through the hard mask and (ii) etching pre-tapered features in the silicon layer or silicon-germanium layer with the first plasma;
supplying a second etching gas mixture different from the first etching gas mixture into the plasma processing chamber; and
forming a second plasma from the second etching gas mixture and overetching the hard mask so as to modify and/or enlarge the first pre-tapered features to form second pre-tapered features in the silicon or silicon-germanium layer with the second plasma.

10. The process of claim 9, wherein:
the first pre-tapered features have a depth of from about 1 nm to about 20 nm; and
the second pre-tapered features (i) have a depth of from about 1 nm to about 50 nm, and (ii) include sidewalls which have a taper of from about 30° to about 85°.

11. The process of claim 9, wherein:
the first etching gas mixture comprises CₓH_{y}F_{z}, where each of x, y and z is >0, oxygen-containing gas and inert gas; and
the second etching gas mixture is oxygen-free and comprises CₓH_{y}F_{z}, where each of x, y and z is >0, and an inert gas.

12. The process of claim 11, wherein:
the first etching gas mixture is supplied into the process chamber at a gas flow rate from about 50 sccm to about 300 sccm of CHF₃, up to about 750 sccm of the inert gas, up to about 40 sccm of O₂, and from about 0 to about 40 sccm of HBr; and
the second etching gas mixture is supplied into the plasma processing chamber at a gas flow rate of from about 50 sccm to about 300 sccm of CHF₃ and up to about 750 sccm of the inert gas.

13. The process of claim 12, wherein:
the first plasma is formed by inductively coupling RF energy into the plasma processing chamber at a chamber pressure of from about 5 mT to about 100 mT; and
the second plasma is formed by inductively coupling RF energy into the plasma processing chamber at a chamber pressure of from about 1 mT to about 50 mT.

14. The process of claim 9, wherein:
the semiconductor substrate includes a pad oxide layer between the silicon or silicon-germanium layer and the hard mask;
the first plasma forms openings defined by substantially vertical or vertical sidewalls in the hard mask and pad oxide layer; and
the second pre-tapered features have sidewalls which extend from the pad oxide layer to the bottom of the respective second pre-tapered features.

15. The process of claim 9, wherein the semiconductor structure comprises a pad oxide layer between a silicon nitride layer and a single crystal silicon layer.

16. A process for forming shallow trenches in a silicon or silicon-germanium layer of a semiconductor structure, comprising:
providing in a plasma processing chamber a semiconductor structure comprising a silicon layer or a silicon-germanium layer, a hard mask over the silicon or silicon-germanium layer, and a patterned soft mask over the hard mask;
supplying a first etching gas mixture into the plasma processing chamber;
forming a first plasma from the first etching gas mixture and (i) etching openings through the hard mask and (ii) etching first pre-tapered features in the silicon or silicon-germanium layer with the first plasma;
supplying a second etching gas mixture which is different from the first etching gas mixture into the plasma processing chamber; and
forming a second plasma from the second etching gas mixture and overetching the hard mask so as to modify and/or enlarge the first pre-tapered features to form second pre-tapered features in the silicon or silicon-germanium layer with the second plasma;
removing the soft mask from the semiconductor structure; and
etching the silicon or silicon-germanium layer to form shallow trenches therein.

17. The process of claim 16, wherein:
the first pre-tapered features have a depth of from about 1 nm to about 20 nm;
the first etching gas mixture comprises CₓH_{y}F_{z}, where each of x, y and z is >0, oxygen-containing gas and inert gas; and
the first plasma is formed by inductively coupling RF energy into the plasma processing chamber at a chamber pressure of from about 5 mT to about 100 mT.

18. The process of claim 16, wherein the semiconductor structure includes a pad oxide layer between the silicon or silicon-germanium layer and the hard mask, the first plasma forms openings defined by substantially vertical or vertical sidewalls in the hard mask and pad oxide layer.

19. The process of claim 16, wherein:
the semiconductor structure includes a pad oxide layer between the silicon or silicon-germanium layer and the hard mask;
the second pre-tapered features (i) have a depth of from about 1 nm to about 50 nm, and (ii) include tapered sidewalls having a taper of from about 30° to about 85° and which extend from the pad oxide layer to the bottom of the respective second pre-tapered features;
the second etching gas mixture is oxygen-free and comprises CₓH_{y}F_{z}, where each of x, y and z is >0, and inert gas; and
the second plasma is formed by inductively coupling RF energy into the plasma processing chamber which is at a pressure of about 5 mT to about 50 mT.

20. The process of claim 16, wherein the semiconductor structure comprises a silicon layer, a pad oxide layer over the silicon layer, and the hard mask over the pad oxide layer.
